(19) United States
(12) Patent Application Publication
(10) Pub. No.: US 2022/0098722 A1
(43) Pub. Date: Mar. 31, 2022

(54) VAPORIZING SYSTEM, SUBSTRATE PROCESSING APPARATUS AND METHOD OF MANUFACTURING SEMICONDUCTOR DEVICE

(71) Applicant: KOKUSAI ELECTRIC CORPORATION, Tokyo (JP)

(72) Inventors: Akinori TANAKA, Toyama (JP); Yuji SAIKI, Toyama (JP)

(73) Assignee: KOKUSAI ELECTRIC CORPORATION, Tokyo (JP)

(21) Appl. No.: 17/476,843

(22) Filed: Sep. 16, 2021

(30) Foreign Application Priority Data
Sep. 28, 2020 (JP) 2020-162171
Aug. 18, 2021 (JP) 2021-133175

(51) Int. Cl. C23C 14/24

(52) U.S. Cl. CPC C23C 14/24; H01L 21/02271

(57) ABSTRACT

Described herein is a technique capable of suppressing the deposition of the residue and also possible to improve the vaporization efficiency. According to one aspect of the technique, there is provided a vaporizing system including: a vaporization chamber provided with a first end and a second end; a first fluid supplier connected to the vaporization chamber at the second end and configured to supply toward the first end a mixed fluid containing a first carrier gas and a liquid source mixed with each other; and a second fluid supplier connected to the vaporization chamber at the first end and configured to supply a second carrier gas such that the second carrier gas flows along an inner wall of the vaporization chamber when being supplied through the first end.

### CROSS-REFERENCE TO RELATED PATENT APPLICATION

This non-provisional U.S. patent application claims priorities under 35 U.S.C. § 119 of Japanese Patent Application No. 2020-162171, filed on Sep. 28, 2020, and Japanese Patent Application No. 2021-133175, filed on Aug. 18, 2021, in the Japanese Patent Office, the entire contents of which are hereby incorporated by reference.

### BACKGROUND

### 1. Field

The present disclosure relates to a vaporizing system, a substrate processing apparatus and a method of manufacturing a semiconductor device.

### 2. Related Art

As a substrate processing apparatus used in a manufacturing process of a semiconductor device, for example, an apparatus configured to process a substrate in a process chamber by supplying a process gas obtained by vaporizing a liquid source to the process chamber may be used. For example, the liquid source is used as a source material for the process gas, and the liquid source is vaporized to generate a vaporized gas (also referred to as a “source gas”). The vaporized gas generated by vaporizing the liquid source is supplied to the process chamber as the process gas.

When the vaporized gas is generated, if the liquid source is not sufficiently vaporized, a residue may remain and be deposited (and accumulated) in a vaporizer (vaporization chamber) in which the liquid source is vaporized.

### SUMMARY

Described herein is a technique capable of suppressing a deposition of a residue and improving a vaporization efficiency.

According to one aspect of the technique of the present disclosure, there is provided a vaporizing system including: a vaporization chamber provided with a first end and a second end; a first fluid supplier connected to the vaporization chamber at the second end and configured to supply toward the first end a mixed fluid containing a first carrier gas and a liquid source mixed with each other; and a second fluid supplier connected to the vaporization chamber at the first end and configured to supply a second carrier gas such that the second carrier gas flows along an inner wall of the vaporization chamber when being supplied through the first end.

### BRIEF DESCRIPTION OF THE DRAWINGS

FIG. 1 is a diagram schematically illustrating a vertical cross-section of a process furnace of a substrate processing apparatus according to one or more embodiments described herein.

FIG. 2 is a diagram schematically illustrating a gas supplier of the substrate processing apparatus according to the embodiments described herein.

FIG. 3 is a block diagram schematically illustrating a configuration of a controller and related components of the substrate processing apparatus according to the embodiments described herein.

FIG. 4 is a flowchart schematically illustrating a substrate processing of forming a film on a substrate by the substrate processing apparatus according to the embodiments described herein.

FIG. 5 is a diagram schematically illustrating a vaporizer used in the substrate processing apparatus according to the embodiments described herein.

FIG. 6 is a diagram schematically illustrating an example of a first fluid supplier of the vaporizer used in the substrate processing apparatus according to the embodiments described herein.

FIG. 7 is a diagram schematically illustrating a nozzle holder of the first fluid supplier of the vaporizer used in the substrate processing apparatus according to the embodiments described herein.

FIG. 8 is a diagram schematically illustrating a nozzle plate cover of the first fluid supplier of the vaporizer used in the substrate processing apparatus according to the embodiments described herein.

FIG. 9 is a diagram schematically illustrating a vertical cross-section of the first fluid supplier of the vaporizer used in the substrate processing apparatus according to the embodiments described herein.

FIGS. 10A and 10B are diagrams schematically illustrating a second fluid supplier of the vaporizer used in the substrate processing apparatus according to the embodiments described herein.

FIG. 11 is a diagram schematically illustrating another example of the first fluid supplier of the vaporizer used in the substrate processing apparatus according to the embodiments described herein.

### DETAILED DESCRIPTION

<Embodiments>

Hereinafter, one or more embodiments (also simply referred to as “embodiments”) according to the technique of the present disclosure will be described with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

(1) Configuration of Substrate Processing Apparatus

First, a configuration of a substrate processing apparatus according to the embodiments described herein will be described. As an example of the substrate processing apparatus according to the embodiments described herein, a batch type vertical substrate processing apparatus used in a part of a manufacturing process of a semiconductor device and configured to perform a process such as a film-forming process to a plurality of substrates simultaneously will be described. Hereinafter, the batch type vertical substrate processing apparatus may also be simply referred to as a “substrate processing apparatus”.

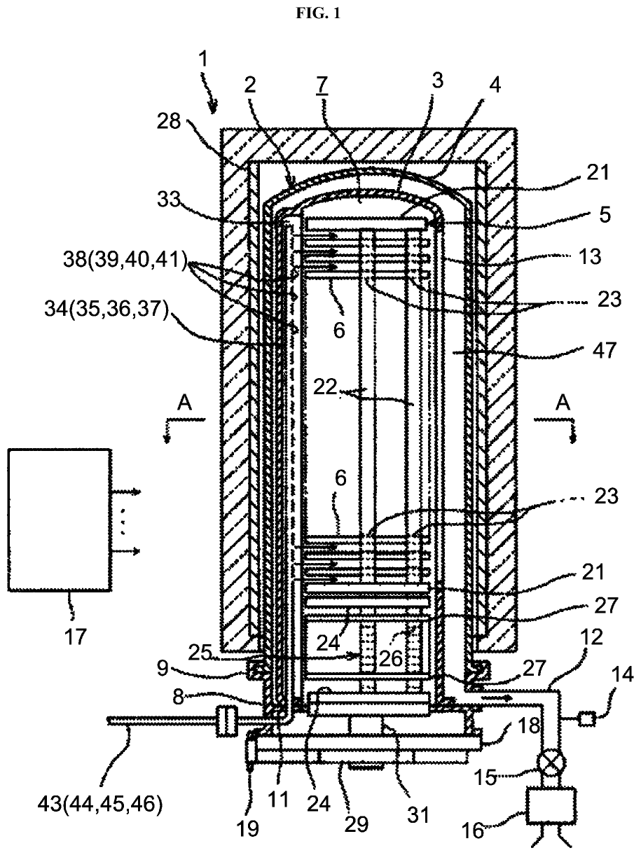

The substrate processing apparatus according to the present embodiments includes a process furnace 1. FIG. 1 is a diagram schematically illustrating an example of the process furnace 1 of the substrate processing apparatus according to the present embodiments.

The process furnace 1 includes a vertical type process tube 2 serving as a reaction tube which is vertically arranged such that a center line thereof is vertical and which is fixedly supported by a housing (not shown). Hereinafter, the vertical type process tube 2 may also be simply referred to as a “process tube 2”. The process tube 2 includes an inner tube 3 and an outer tube 4. The inner tube 3 and the outer tube 4 are integrally formed as a single body. For example, each of the inner tube 3 and the outer tube 4 is made of a high heat resistant material such as quartz (SiO₂), silicon carbide (SiC), a composite material of the quartz and a composite material of the silicon carbide.

The inner tube 3 is of a cylindrical shape with a closed upper end and an open lower end, and a boat 5 serving as a substrate retainer (which is a substrate retaining structure) is accommodated in a cylinder of the inner tube 3. A plurality of wafers including a wafer 6 serving as a substrate are vertically arranged (stacked) in a horizontal orientation in a multistage manner by the boat 5. Hereinafter, the plurality of wafers including the wafer 6 may also be simply referred to as wafers 6. A process chamber 7 in which the wafers 6 are accommodated and processed are defined by an inner space of the inner tube 3 in which the boat 5 is accommodated. A lower end opening of the inner tube 3 constitutes a furnace opening through which the boat 5 holding (or supporting) the wafers 6 is transferred (or loaded) into or transferred (or unloaded) out of the process chamber 7. Therefore, an inner diameter of the inner tube 3 is set to be greater than a maximum outer diameter of the boat 5 holding the wafers 6.

The outer tube 4 is of a cylindrical shape with a closed upper end and an open lower end. An inner diameter of the outer tube 4 is set to be greater than that of the inner tube 3. The outer tube 4 is aligned in a manner concentric with the inner tube 3 so as to surround an outer side of the inner tube 3. The lower end of the outer tube 4 is provided at a flange 9 of a manifold 8 via an O-ring (not shown), and is airtightly sealed by the O-ring.

The lower end of the inner tube 3 is placed on a ring structure 11 of a disk shape provided on an inner peripheral surface of the manifold 8. The inner tube 3 and the outer tube 4 are detachably attached to the manifold 8 such that a maintenance operation, an inspection operation or a cleaning operation of each of the inner tube 3 and the outer tube 4 can be performed. As the manifold 8 is supported by the housing (not shown), the process tube 2 is vertically installed.

As described above, the inner space of the inner tube 3 is referred to as the process chamber 7. However, hereinafter, an inner space of the outer tube 4 may also be referred to as the process chamber 7.

An exhaust pipe 12 through which an inner atmosphere of the process chamber 7 is exhausted is connected to a part of a side wall of the manifold 8. An exhaust port through which the inner atmosphere of the process chamber 7 is exhausted is provided at a connecting portion between the manifold 8 and the exhaust pipe 12. An inner side of the exhaust pipe 12 communicates via the exhaust port with an exhaust path 47, which is described later, formed (or defined) by a gap provided between the inner tube 3 and the outer tube 4. A cross-sectional shape of the exhaust path 47 is of a substantially circular ring shape. As a result, it is possible to uniformly exhaust the inner atmosphere of the process chamber 7 through an exhaust hole 13, which is described later, provided in the inner tube 3 from an upper end to a lower end of the exhaust hole 13. That is, it is possible to uniformly exhaust the inner atmosphere of the process chamber 7 from the entirety of the wafers 6 accommodated in the boat 5.

A pressure sensor 14, an APC (Automatic Pressure Controller) valve 15 serving as a pressure regulator and a vacuum pump 16 serving as a vacuum exhaust apparatus are sequentially installed at the exhaust pipe 12 in this order from an upstream side to a downstream side of the exhaust pipe 12. The vacuum pump 16 is configured to be able to vacuum-exhaust the inner atmosphere of the process chamber 7 such that an inner pressure of the process chamber 7 reaches and is maintained at a predetermined pressure (vacuum degree). A controller 17 is electrically connected to the pressure sensor 14 and the APC valve 15. The controller 17 is configured to control an opening degree of the APC valve 15 based on a pressure detected by the pressure sensor 14 such that the inner pressure of the process chamber 7 reaches and is maintained at a desired pressure at a desired timing.

An exhauster (which is an exhaust structure or an exhaust system) according to the present embodiments is constituted mainly by the exhaust pipe 12, the pressure sensor 14 and the APC valve 15. The exhauster may further include the vacuum pump 16. For example, a trap apparatus configured to capture reaction by-products or an unreacted source gas in an exhaust gas (that is, the inner atmosphere of the process chamber 7 exhausted through the exhauster) or a detoxification apparatus configured to get rid of a corrosive component or a toxic component contained in the exhaust gas may be connected to the exhaust pipe 12. In such a case, the exhauster may further include the trap apparatus or the detoxification apparatus.

A seal cap 18 capable of airtightly sealing a lower end opening of the manifold 8 is provided under the manifold 8. The seal cap 18 is in contact with the lower end of the manifold 8 from thereunder. The seal cap 18 is of a disk shape, and an outer diameter of the seal cap 18 is equal to or greater than an outer diameter of the outer tube 4. The seal cap 18 is positioned in a horizontal orientation, and elevated or lowered in a vertical direction by a boat elevator 19 (described later) installed vertically outside the process tube 2.

The boat 5 holding the wafers 6 is vertically provided and supported on the seal cap 18. The boat 5 includes a pair of upper and lower end plates 21 and a plurality of support columns 22 provided between the upper and lower end plates 21 in the vertical direction. For example, each of the upper and lower end plates 21 and the plurality of support columns 22 are made of a heat resistant material such as quartz (SiO₂), silicon carbide (SiC), a composite material of the quartz and a composite material of the silicon carbide. A plurality of support recesses 23 are engraved at each of the support columns 22 at equal intervals in a lengthwise direction of each of the support columns 22. By inserting edges of the wafers 6 to the support recesses 23 engraved at the same stage of each of the support columns 22, respectively, the boat 5 supports the wafers 6 vertically arranged in a multistage manner while the wafers 6 are horizontally oriented with their centers aligned with one another.

A pair of upper and lower auxiliary end plates 24 are supported by a plurality of auxiliary support columns 25 between the boat 5 and the seal cap 18. A plurality of support recesses 26 are engraved at each of the auxiliary support columns 25. A plurality of heat insulating plates 27 of a disk shape are supported by the plurality of support recesses 26 in a horizontal orientation and in a multistage manner. For example, each of the plurality of heat insulating plates 27 is made of a heat resistant material such as quartz (SiO₂) and silicon carbide (SiC). With such a configuration, the plurality of heat insulating plates 27 is capable of suppressing the transmission of the heat from a heater 28 to the manifold 8. In addition, it is possible to suppress a temperature drop in a lower region of the wafers 6 accommodated in the boat 5.

A rotator 29 configured to rotate the boat 5 is provided at the seal cap 18 opposite to the process chamber 7. A rotating shaft 31 of the rotator 29 penetrates the seal cap 18 and supports the boat 5 from thereunder. As the rotator 29 rotates the rotating shaft 31, the wafers 6 in the process chamber 7 are rotated.

The seal cap 18 may be elevated or lowered in the vertical direction by the boat elevator 19 serving as an elevator. When the seal cap 18 is elevated or lowered in the vertical direction by the boat elevator 19 serving as a transfer structure (transfer device), the boat 5 may be transferred (loaded) into the process chamber 7 or transferred (unloaded) out of the process chamber 7.

The heater 28 serving as a part of a heating structure (heating device) is provided outside the outer tube 4 so as to surround the outer tube 4. The heater 28 is capable of heating an inner side of the process tube 2 such that a uniform temperature distribution or a predetermined temperature distribution of an inner temperature of the process tube 2 can be obtained. The heater 28 is vertically installed while being supported by the housing (not shown) of the substrate processing apparatus. For example, the heater 28 is configured as a resistance heating heater such as a carbon heater.

A temperature sensor 32 serving as a temperature detector is provided in the process tube 2. The heating structure (heating device) according to the present embodiments is constituted mainly by the heater 28 and the temperature sensor 32.

A spare chamber 33 of a channel shape is provided on a side wall of the inner tube 3 at a location opposite to the exhaust hole 13 described later by 180°. The spare chamber 33 protrudes outward in a radial direction of the inner tube 3 from the side wall of the inner tube 3 and extends along the vertical direction. An inner wall of the spare chamber 33 constitutes a part of an inner wall of the process chamber 7.

Nozzles 34, 35, 36 and 37 through which a gas such as a source gas and a reactive gas described later is supplied into the process chamber 7 are provided in the spare chamber 33. Each of the nozzles 34, 35, 36 and 37 is installed in the spare chamber 33 so as to extend in a stacking direction of the wafers 6 from a lower portion toward an upper portion of the spare chamber 33 along the inner wall of the spare chamber 33 (that is, the inner wall of the process chamber 7). That is, the nozzles 34, 35, 36 and 37 are installed in a region that horizontally surrounds a wafer arrangement region (in which the wafers 6 are accommodated) on a side of the wafer arrangement region along the wafer arrangement region.

Each of the nozzles 34, 35, 36 and 37 may include an L-shaped long nozzle. Horizontal portions of the nozzles 34, 35, 36 and 37 are installed so as to penetrate the manifold 8. Vertical portions of the nozzles 34, 35, 36 and 37 are installed in the spare chamber 33 so as to extend upward from a lower portion toward an upper portion of the wafer arrangement region. Although one nozzle 34 is shown in FIG. 1 for convenience, four nozzles 34, 35, 36 and 37 are actually provided.

A plurality of gas supply holes 38, a plurality of gas supply holes 39, a plurality of gas supply holes 40 and a plurality of gas supply holes 41 are provided at side surfaces of the nozzles 34, 35, 36 and 37, respectively. The gas such as the source gas and the reactive gas is supplied through the plurality of gas supply holes 38, the plurality of gas supply holes 39, the plurality of gas supply holes 40 and the plurality of gas supply holes 41. An opening area of each of the gas supply holes 38, the gas supply holes 39, the gas supply holes 40 and the gas supply holes 41 may be the same, or may be increased or decreased as it goes from a lower portion to an upper portion of each of the nozzles 34, 35, 36 and 37. Each of the gas supply holes 38, the gas supply holes 39, the gas supply holes 40 and the gas supply holes 41 is provided at the same pitch.

End portions of the horizontal portions of the nozzles 34, 35, 36 and 37 penetrating the manifold 8 are connected to gas supply pipes 43, 44, 45 and 46 serving as gas supply lines provided outside the process tube 2, respectively.

As described above, according to the present embodiments, the gas such as the source gas and the reactive gas is supplied through the nozzles 34, 35, 36 and 37 provided in the spare chamber 33. Then, the gas is ejected into the process chamber 7 in the vicinity of the wafers 6 through the plurality of gas supply holes 38, the plurality of gas supply holes 39, the plurality of gas supply holes 40 and the plurality of gas supply holes 41.

The exhaust hole 13 is a through-hole facing the nozzles 34, 35, 36 and 37, and is provided at the side wall of the inner tube 3. That is, the exhaust hole 13 is provided at a location opposite to the spare chamber 33 by 180°. For example, the exhaust hole 13 may be of a narrow slit-shaped through-hole elongating vertically. As described above, the exhaust path 47 is formed (or defined) by the gap provided between the inner tube 3 and the outer tube 4, and the exhaust path 47 communicates with the process chamber 7 through the exhaust hole 13. Therefore, the gas supplied into the process chamber 7 through the plurality of gas supply holes 38, the plurality of gas supply holes 39, the plurality of gas supply holes 40 and the plurality of gas supply holes 41 flows into the exhaust path 47 through the exhaust hole 13, is supplied into the exhaust pipe 12 through the exhaust port, and is discharged (exhausted) out of the process chamber 7.

The gas supplied in the vicinity of the wafers 6 in the process chamber 7 through the plurality of gas supply holes 38, the plurality of gas supply holes 39, the plurality of gas supply holes 40 and the plurality of gas supply holes 41 flows in a horizontal direction (that is, in a direction parallel to surfaces of the wafers 6). The gas that has flowed in the horizontal direction is exhausted through the exhaust hole 13 into the exhaust path 47. That is, the gas ejected into the process chamber 7 mainly flows parallel to the surfaces of the wafers 6, that is, in the horizontal direction. Thereby, it is possible to uniformly supply the gas to each of the wafers 6, and is also possible to uniformize a thickness of a film formed on each of the wafers 6. The exhaust hole 13 is not limited to the slit-shaped through-hole. For example, the exhaust hole 13 may be configured as a plurality of holes.

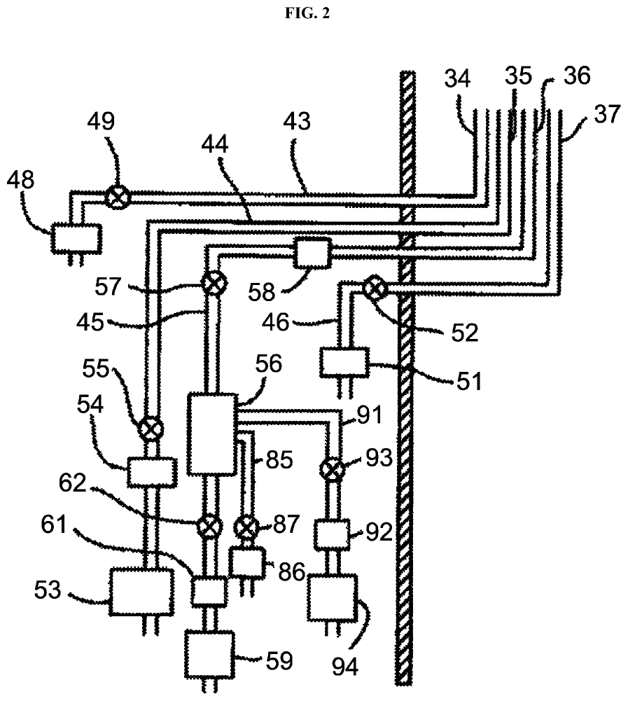

Subsequently, a gas supplier (which is a gas supply structure or a gas supply system) according to the present embodiments will be described with reference to FIG. 2. FIG. 2 is a diagram schematically illustrating the gas supplier according to the present embodiments.

A mass flow controller (MFC) 48 serving as a flow rate controller (flow rate control structure) and a valve 49 serving as an opening/closing valve are sequentially installed at the gas supply pipe 43 in this order from an upstream side to a downstream side of the gas supply pipe 43. For example, nitrogen (N₂) gas serving as an inert gas is supplied to the process chamber 7 through the gas supply pipe 43 and the nozzle 34. A first inert gas supplier (which is a first inert gas supply structure or a first inert gas supply system) is constituted mainly by the nozzle 34, the gas supply pipe 43, the MFC 48 and the valve 49.

A mass flow controller (MFC) 51 serving as a flow rate controller (flow rate control structure) and a valve 52 serving as an opening/closing valve are sequentially installed at the gas supply pipe 46 in this order from an upstream side to a downstream side of the gas supply pipe 46. For example, the nitrogen (N₂) gas serving as an inert gas is supplied to the process chamber 7 through the gas supply pipe 46 and the nozzle 37. A second inert gas supplier (which is a second inert gas supply structure or a second inert gas supply system) is constituted mainly by the nozzle 37, the gas supply pipe 46, the MFC 51 and the valve 52.

An inert gas supplier (which is an inert gas supply structure or an inert gas supply system) is constituted by at least one among the first inert gas supplier and the second inert gas supplier. The first inert gas supplier and the second inert gas supplier may be used independently depending on a processing (that is, a substrate processing described later) of the wafer 6. However, by using both the first inert gas supplier and the second inert gas supplier, it is possible to process the wafers 6 uniformly. In addition, it is preferable that the nozzle 34 and the nozzle 37 are arranged such that another nozzle (or nozzles) is (or are) interposed therebetween. With such a configuration, it is possible to improve a process uniformity of the wafers 6.

A reactive gas activator (which is a reactive gas activating structure) 53, a mass flow controller (MFC) 54 serving as a flow rate controller (flow rate control structure) and a valve 55 serving as an opening/closing valve are sequentially installed at the gas supply pipe 44 in this order from an upstream side to a downstream side of the gas supply pipe 44. The reactive gas activator 53 may also be simply referred to as an activator 53. The nozzle 35 is connected to a front end (tip) of the gas supply pipe 44.

A reactive gas supply source (not shown) is connected to the reactive gas activator 53 on the upstream side of the gas supply pipe 44. A reactive gas supplier (which is a reactive gas supply structure or a reactive gas supply system) is constituted mainly by the nozzle 35, the gas supply pipe 44, the reactive gas activator 53, the MFC 54 and the valve 55. For example, an apparatus such as an ozonizer, a plasma generator and a preheating device may be used as the reactive gas activator 53.

A vaporizer 56 serving as a vaporizing system (vaporizing structure) configured to vaporize a liquid source (which is a source material of the source gas) to generate a vaporized gas serving as the source gas is provided at the gas supply pipe 45. A valve 57 serving as an opening/closing valve and a gas filter 58 are sequentially installed at the gas supply pipe 45 in this order from an upstream side to a downstream side of the gas supply pipe 45 at a downstream side of the vaporizer 56. The nozzle 36 is connected to a front end (tip) of the gas supply pipe 45. By opening the valve 57, the vaporized gas generated in the vaporizer 56 is supplied to the process chamber 7 via the nozzle 36. A source gas supplier (which is a source gas supply structure or a source gas supply system) is constituted mainly by the nozzle 36, the gas supply pipe 45, the vaporizer 56, the valve 57 and the gas filter 58. The source gas supplier may also be referred to as a vaporized gas supplier (which is a vaporized gas supply structure or a vaporized gas supply system). The source gas supplier may further include a carrier gas supplier (which is a carrier gas supply structure or a carrier gas supply system) such as a first carrier gas supplier and a second carrier gas supplier and a liquid source supplier, which will be described later.

A liquid source tank 59, a liquid flow rate controller such as an LMFC (liquid mass flow controller) 61 and a valve 62 serving as an opening/closing valve are sequentially installed at the gas supply pipe 45 in this order from the upstream side to the downstream side of the gas supply pipe 45 at an upstream side of the vaporizer 56. A supply amount of the liquid source into the vaporizer 56 (that is, a supply flow rate of the vaporized gas vaporized in the vaporizer 56 and supplied to the process chamber 7) is controlled by the LMFC 61. The liquid source supplier (which is a liquid source supply structure or a liquid source supply system) is constituted mainly by the gas supply pipe 45, the liquid source tank 59, the LMFC 61 and the valve 62.

In addition, the inert gas serving as a first carrier gas is supplied to the vaporizer 56 through a gas supply pipe 85, and the inert gas serving as a second carrier gas is supplied to the vaporizer 56 through a gas supply pipe 91. An MFC 86 and a valve 87 are sequentially installed at the gas supply pipe 85 in this order from an upstream side to a downstream side of the gas supply pipe 85. By diluting the vaporized gas generated by the vaporizer 56 with a carrier gas, it is possible to adjust the process uniformity between the wafers 6 such as a thickness uniformity of the film between the wafers 6 accommodated in the boat 5. A first carrier gas supplier (which is a first carrier gas supply structure or a first carrier gas supply system) is constituted mainly by the gas supply pipe 85, the MFC 86 and the valve 87, and a second carrier gas supplier (which is a second carrier gas supply structure or a second carrier gas supply system) is constituted mainly by the gas supply pipe 91, an MFC 92, a valve 93 and a heater 94 described later.

The source gas is supplied to the process chamber 7 through the gas supply pipe 45 via components such as the LMFC 61, the vaporizer 56, the gas filter 58 and the nozzle 36. The vaporized gas obtained by vaporizing the liquid source may be used as the source gas. For example, the liquid source that is in a liquid state at the normal temperature and the normal pressure is stored in the liquid source tank 59.

The vaporizer 56 will be described in detail later.

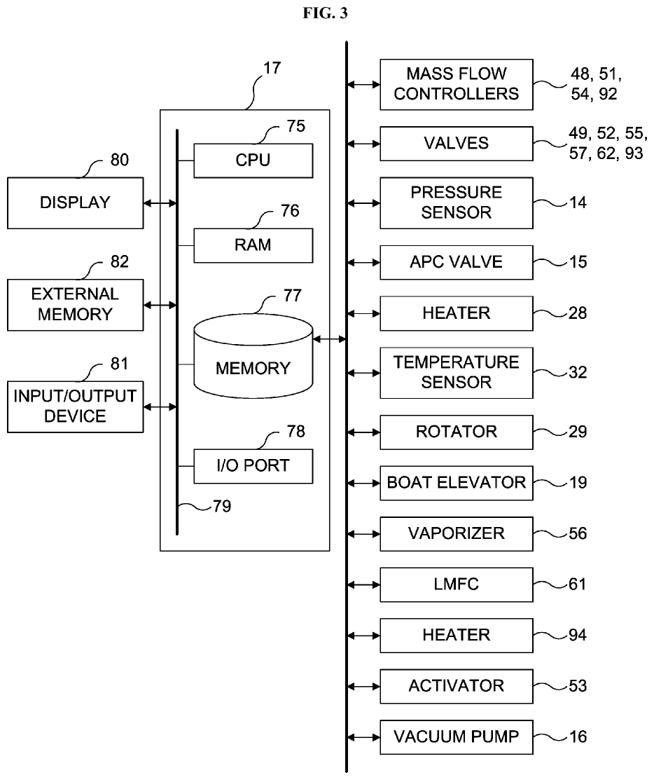

Subsequently, the controller 17 serving as a control structure (control device) and related components connected thereto will be described. FIG. 3 is a block diagram schematically illustrating a configuration of the controller 17 and the related components connected to the controller 17 according to the present embodiments.

The controller 17 is constituted by a computer including a CPU (Central Processing Unit) 75, a RAM (Random Access Memory) 76, a memory 77 and an I/O port 78. The RAM 76, the memory 77 and the I/O port 78 may exchange data with the CPU 75 through an internal bus 79. For example, a display 80 such as a display device and an input/output device 81 such as a touch panel may be connected to the controller 17.

The memory 77 is configured by a component such as a flash memory and a hard disk drive (HDD). For example, a control program configured to control the operation of the substrate processing apparatus or a process recipe containing information on the sequences and conditions of the substrate processing described later is readably stored in the memory 77. The process recipe is obtained by combining steps of the substrate processing described later such that the controller 17 can execute the steps to acquire a predetermined result, and functions as a program. Hereafter, the process recipe and the control program may be collectively or individually referred to as a “program”. In the present specification, the term “program” may refer to the process recipe alone, may refer to the control program alone, or may refer to a combination of the process recipe and the control program. The RAM 76 functions as a memory area (work area) where a program or data read by the CPU 75 is temporarily stored.

The I/O port 78 is connected to the above-described components constituting the substrate processing apparatus such as the MFCs 48, 51, 54, 86 and 92, the valves 49, 52, 55, 57, 62, 87 and 93, the pressure sensor 14, the APC valve 15, the vacuum pump 16, the boat elevator 19, the heater 28, the rotator 29, the temperature sensor 32, the activator 53, the vaporizer 56, the LMFC 61 and the heater 94 described later.

The CPU 75 is configured to read the control program from the memory 77 and execute the read control program. In addition, the CPU 75 is configured to read the process recipe from the memory 77 in accordance with an operation command inputted from the input/output device 81. According to the contents of the read process recipe, the CPU 75 may be configured to control various operations such as flow rate adjusting operations for various gases by the MFCs 48, 51, 54, 86 and 92, a flow rate adjusting operation for the liquid source by the LMFC 61, opening and closing operations of the valves 49, 52, 55, 57, 62, 87 and 93, an opening and closing operation of the APC valve 15, a pressure adjusting operation by the APC valve 15 based on the pressure sensor 14, a temperature adjusting operation by the heater 28 based on the temperature sensor 32, a start and stop of the vacuum pump 16, an operation of adjusting the rotation and the rotation speed of the boat 5 by the rotator 29, an elevating and lowering operation of the boat 5 by the boat elevator 19 and a heat adjusting operation of the second carrier gas (inert gas) by the heater 94.

The controller 17 may be embodied by a dedicated computer or by a general-purpose computer. According to the present embodiments, for example, the controller 17 may be embodied by preparing an external memory 82 storing the program and by installing the program onto the general-purpose computer using the external memory 82. For example, the external memory 82 may include a semiconductor memory such as a USB memory. A method of providing the program to the computer is not limited to the external memory 82. For example, the program may be supplied to the computer (general-purpose computer) using communication means such as the Internet and a dedicated line instead of the external memory 82. The memory 77 or the external memory 82 may be embodied by a non-transitory computer readable recording medium. Hereafter, the memory 77 and the external memory 82 may be collectively or individually referred to as a “recording medium”. In the present specification, the term “recording medium” may refer to the memory 77 alone, may refer to the external memory 82 alone or may refer to both of the memory 77 and the external memory 82.

(2) Sequence of Substrate Processing

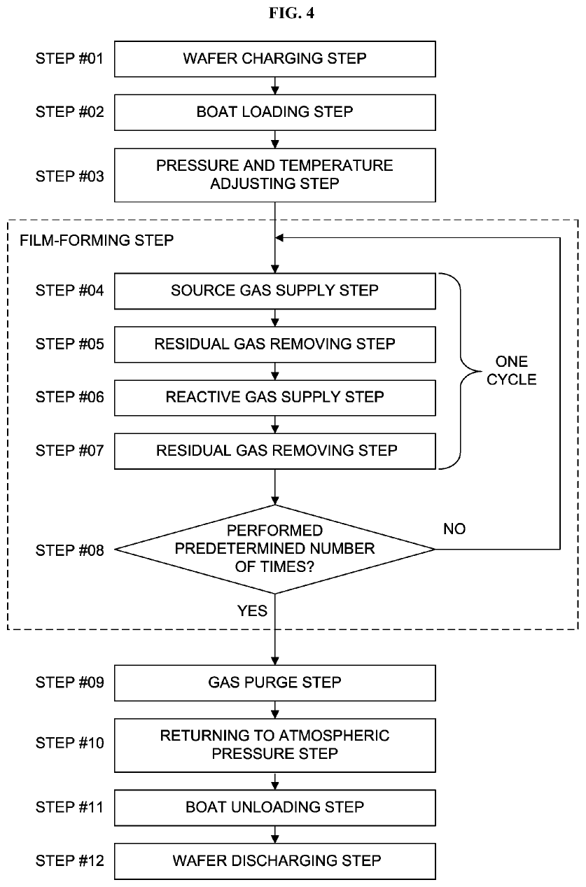

Hereinafter, an exemplary sequence of the substrate processing (that is, a film-forming process) of forming a film on a substrate (that is, the wafer 6), which is a part of the manufacturing process of the semiconductor device by using the process furnace 1 of the substrate processing apparatus described above, will be described with reference to FIG. 4. Hereinafter, operations of components constituting the substrate processing apparatus are controlled by the controller 17.

In the present specification, the term “wafer” may refer to “a wafer itself”, or may refer to “a wafer and a stacked structure (aggregated structure) of a predetermined layer (or layers) or a film (or films) formed on a surface of a wafer”. That is, the term “wafer” may collectively refer to the wafer and the layers or the films formed on the surface of the wafer. In the present specification, the term “a surface of a wafer” may refer to “a surface (exposed surface) of a wafer itself”, or may refer to “a surface of a predetermined layer or a film formed on a wafer, i.e. a top surface (uppermost surface) of the wafer as a stacked structure”.

Thus, in the present specification, “supplying a predetermined gas to a wafer” may refer to “directly supplying a predetermined gas to a surface (exposed surface) of a wafer itself” or may refer to “supplying a predetermined gas to a predetermined layer or a film formed on a wafer, i.e. a top surface (uppermost surface) of the wafer as a stacked structure”. In the present specification “forming a predetermined layer (or film) on a wafer” may refer to “directly forming a predetermined layer (or film) on a surface of (exposed surface) of a wafer itself” or may refer to “forming a predetermined layer (or film) on a layer or a film formed on a wafer, i.e. a top surface (uppermost surface) of the wafer as a stacked structure”.

In the present specification, the terms “substrate” and “wafer” may be used as substantially the same meaning. That is, the term “substrate” may be substituted by “wafer” and vice versa.

Hereinafter, the substrate processing will be described.

STEP #01

First, the wafers 6 are transferred (charged) into the boat 5 (wafer charging step).

STEP #02

The boat 5 charged with the wafers 6 is elevated by the boat elevator 19 and loaded (transferred) into the process chamber 7 (boat loading step). With the boat 5 loaded, the seal cap 18 airtightly seals the lower end opening of the manifold 8.

STEP #03

After the boat 5 is loaded into the process chamber 7, the vacuum pump 16 vacuum-exhausts the inner atmosphere of the process chamber 7 until the inner pressure of the process chamber 7 reaches and is maintained at a desired pressure (vacuum degree). In the STEP #03, the inner pressure of the process chamber 7 is measured by the pressure sensor 14, and the APC valve 15 is feedback-controlled based on pressure information measured by the pressure sensor 14 (pressure adjusting step). In the STEP #03, the heater 28 heats the process chamber 7 until an inner temperature of the process chamber 7 reaches and is maintained at a desired temperature. In the STEP #03, the amount of the current supplied to the heater 28 is feedback-controlled based on temperature information detected by the temperature sensor 32 such that a desired temperature distribution of the inner temperature of the process chamber 7 is obtained (temperature adjusting step). Subsequently, as the rotator 29 rotates the boat 5, the wafers 6 are rotated.

The vacuum pump 16 continuously vacuum-exhausts the inner atmosphere of the process chamber 7, the heater 28 continuously heats the process chamber 7, and the rotator 29 continuously rotates the boat 5 and the wafers 6 until at least the substrate processing of the wafers 6 is completed.

Subsequently, a film-forming step of forming the film is performed by supplying a metal-containing gas serving as the source gas and an oxidizing agent serving as the reactive gas to the process chamber 7. In the film-forming step, four steps of STEP #04, STEP #05, STEP #06 and STEP #07 are sequentially performed.

STEP #04 First, the valve 57 of the gas supply pipe 45 is opened to supply the source gas into the gas supply pipe 45 via the vaporizer 56 and the gas filter 58. The source gas supplied in the gas supply pipe 45 is supplied to the process chamber 7 through the plurality of gas supply holes 40 of the gas supply hole 40 of the nozzle 36 in a state where a flow rate of the liquid source is adjusted by the LMFC 61 and the liquid source is vaporized by the vaporizer 56 to generate the source gas, and is exhausted through the exhaust pipe 12.

In the STEP #04, in parallel with the supply of the source gas, the valve 49 is opened to supply the inert gas such as the N₂ through the gas supply pipe 43, the nozzle 34 and the plurality of gas supply holes 38, and the valve 52 is opened to supply the inert gas such as the N₂ through the gas supply pipe 46, the nozzle 37 and the plurality of gas supply holes 41.

In the STEP #04, for example, the opening degree of the APC valve 15 is appropriately adjusted (controlled) to adjust the inner pressure of the process chamber 7 to a predetermined pressure ranging from 100 Pa to 500 Pa. In the STEP #04, for example, a supply flow rate of the liquid source (source gas) adjusted by the LMFC 61 may be set to a predetermined flow rate ranging from 0.045 g/minute to 5.0 g/minute. For example, a supply time (time duration) of exposing (supplying) the source gas to the wafers 6 may be set to a predetermined amount of time ranging from 10 seconds to 300 seconds. In the STEP #04, for example, a temperature of the heater 28 may be set such that a temperature of the wafer 6 reaches and is maintained at a temperature ranging from 150° C. to 300° C. By supplying the source gas, for example, a metal-containing layer is formed on the wafer 6.

STEP #05

After the metal-containing layer is formed, the valve 57 is closed to stop the supply of the source gas to the process chamber 7. In the STEP #05, with the APC valve 15 of the exhaust pipe 12 open, the vacuum pump 16 vacuum-exhausts the inner atmosphere of the process chamber 7 to remove a residual gas in the process chamber 7 such as the source gas which did not react or which contributed to the formation of the metal-containing layer out of the process chamber 7.

In the STEP #05, with the valves 49 and 52 open, the N₂ gas serving as the inert gas is continuously supplied into the process chamber 7. The N₂ gas serves as a purge gas, which improves the efficiency of removing the residual gas in the process chamber 7 such as the source gas which did not react or which contributed to the formation of the metal-containing layer out of the process chamber 7.

In the STEP #05, the gas remaining in the process chamber 7 may not be completely discharged (or exhausted) or the process chamber 7 may not be completely purged. Even when a small amount of the gas remains in the process chamber 7, the small amount of the gas remaining in the process chamber 7 does not adversely affect a subsequent step (that is, the STEP #06). Therefore, in the STEP #05, the N₂ gas may not be supplied into the process chamber 7 at a large flow rate. For example, a purge operation of purging the process chamber 7 may be performed by supplying the N₂ gas of an amount equal to a volume of the outer tube 4 (or the process chamber 7) such that the STEP #06 will not be adversely affected. By not completely purging the process chamber 7 as described above, it is possible to shorten a purge time for purging the process chamber 7, and to improve the throughput. It is also possible to reduce the consumption of the N₂ gas to the minimum.

STEP #06

After the residual gas in the process chamber 7 is removed, the valve 55 of the gas supply pipe 44 is opened to supply the reactive gas into the process chamber 7. Specifically, the reactive gas is activated by the activator 53, and a flow rate of the reactive gas is adjusted by the MFC 54. Then, the reactive gas whose flow rate is adjusted is supplied into the process chamber 7 through the plurality of gas supply holes 39 of the nozzle 35, and is exhausted through the exhaust pipe 12. In the STEP #06, in parallel with the supply of the reactive gas, the valve 49 is opened to supply the inert gas such as the N₂ through the gas supply pipe 43, the nozzle 34 and the plurality of gas supply holes 38, and the valve 52 is opened to supply the inert gas such as the N₂ through the gas supply pipe 46, the nozzle 37 and the plurality of gas supply holes 41.

In the STEP #06, when the reactive gas is supplied, for example, the opening degree of the APC valve 15 is appropriately adjusted (controlled) to adjust the inner pressure of the process chamber 7 to a predetermined pressure ranging from 100 Pa to 500 Pa. In the STEP #06, for example, a supply flow rate of the reactive gas adjusted by the MFC 54 may be set to a predetermined flow rate ranging from 10 SLM to 90 SLM. For example, a supply time (time duration) of exposing (supplying) the reactive gas to the wafers 6 may be set to a predetermined amount of time ranging from 10 seconds to 300 seconds. In the STEP #06, similar to the STEP #04, for example, the temperature of the heater 28 may be set such that the temperature of the wafer 6 reaches and is maintained at a temperature ranging from 150° C. to 300° C. By supplying the reactive gas, for example, a metal oxide layer is formed by oxidizing the metal-containing layer formed on the wafer 6 in the STEP #04.

STEP #07

After the metal oxide layer is formed, the valve 55 is closed to stop the supply of the reactive gas to the process chamber 7. In the STEP #07, with the APC valve 15 of the exhaust pipe 12 open, the vacuum pump 16 vacuum-exhausts the inner atmosphere of the process chamber 7 to remove a residual gas in the process chamber 7 such as the reactive gas which did not react or which contributed to the formation of the metal oxide layer out of the process chamber 7.

In the STEP #07, with the valves 49 and 52 open, the N₂ gas serving as the inert gas is continuously supplied into the process chamber 7. The N₂ gas serves as the purge gas, which improves the efficiency of removing the residual gas in the process chamber 7 such as the reactive gas which did not react or which contributed to the formation of the metal oxide layer out of the process chamber 7.

In the STEP #07, the gas remaining in the process chamber 7 may not be completely discharged (or exhausted) or the process chamber 7 may not be completely purged. Even when a small amount of the gas remains in the process chamber 7, the small amount of the gas remaining in the process chamber 7 does not adversely affect the STEP #04 when the STEP #04 is performed again. Therefore, in the STEP #07, the N₂ gas may not be supplied into the process chamber 7 at a large flow rate. For example, the purge operation of purging the process chamber 7 may be performed by supplying the N₂ gas of an amount equal to the volume of the outer tube 4 (or the process chamber 7) such that the STEP #04 will not be adversely affected. By not completely purging the process chamber 7 as described above, it is possible to shorten the purge time for purging the process chamber 7, and to improve the throughput. It is also possible to reduce the consumption of the N₂ gas to the minimum.

STEP #08

In the STEP #08, the controller 17 determines whether a cycle including the STEP #04, the STEP #05, the STEP #06 and the STEP #07 is performed a predetermined number of times. By performing the cycle at least once, it is possible to form a metal oxide film of a predetermined thickness on the wafer 6. It is preferable that the cycle described above is repeatedly performed a plurality of times. By performing the cycle described above a plurality of times, it is possible to form the metal oxide film of a predetermined thickness on the wafer 6.

STEP #09

After the metal oxide film is formed, the valves 49 and 52 are opened to supply the N₂ gas into the process chamber 7. The N₂ gas serves as the purge gas. Thereby, the process chamber 7 is purged with the inert gas, and the gas remaining in the process chamber 7 is removed out of the process chamber 7.

STEP #10

After the inner atmosphere of the process chamber 7 is replaced with the inert gas, the inner pressure of the process chamber 7 is returned to the normal pressure (atmospheric pressure) (returning to atmospheric pressure step).

STEP #11

Thereafter, the seal cap 18 is lowered by the boat elevator 19 and the lower end opening of the manifold 8 is opened. The boat 5 with the processed wafers 6 charged therein is unloaded out of the process tube 2 through the lower end opening of the manifold 8 (boat unloading step).

STEP #12

Finally, the processed wafers 6 are transferred (discharged) out of the boat 5 (wafer discharging step). Thereby, the substrate processing is completed.

(3) Details of Vaporizer 56

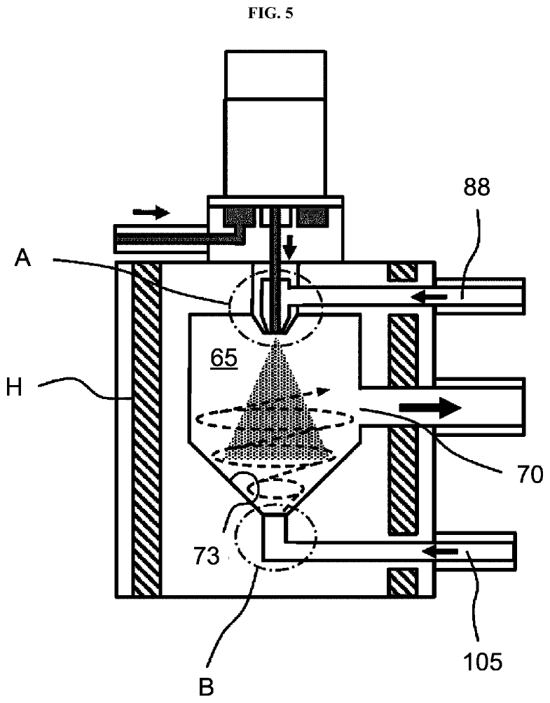

Subsequently, the vaporizer 56 according to the present embodiments will be described in detail with reference to FIGS. 5 through 10B.

FIG. 5 is a diagram schematically illustrating the vaporizer 56. As described above, the vaporizer 56 serving as the vaporizing system is configured to vaporize the liquid source to generate the vaporized gas serving as the source gas. Therefore, the vaporizer 56 includes a vaporization chamber 65 serving as a space in which the vaporized gas is generated.

The vaporization chamber 65 is configured as a tubular structure. One end (also referred to as a “first end”) of the tubular structure (that is, the vaporization chamber 65) is provided on a lower portion of FIG. 5, and a second fluid supplier (which is a second fluid supply structure) “B”, which will be described in detail later, is provided at the first end of the tubular structure. In addition, the other end (also referred to as a “second end”) of the tubular structure (that is, the vaporization chamber 65) is provided on an upper portion of FIG. 5, and a first fluid supplier (which is a first fluid supply structure) “A”, which will be described in detail later, is provided at the second end of the tubular structure.

A tapered portion 73 is provided so as to suppress a stagnation or a turbulence of the gas supplied to the vaporization chamber 65. The tapered portion 73 is provided on an inner wall of the vaporization chamber 65 at at least on a lower side of the vaporization chamber 65, that is, at the first end of the vaporization chamber 65 where the second fluid supplier B is located.

A surface treatment is performed on a surface of the inner wall of the vaporization chamber 65 so as to suppress an adhesion of the liquid source, and more specifically, to prevent the liquid source not vaporized in the vaporization chamber 65 from adhering to and stagnating on the surface of the inner wall of the vaporization chamber 65. Specifically, as the surface treatment, a precision polishing such as an electric field composite polishing may be performed. According to the electric field composite polishing, it is possible to obtain a nano-level ultra-smooth surface when applied to a conductive metal. Therefore, by reducing a surface roughness of the surface of the inner wall of the vaporization chamber 65 by the precision polishing such as the electric field composite polishing, a rolling property of the liquid source is enhanced. As such, even when the liquid source adheres to the surface of the inner wall of the vaporization chamber 65, the liquid source is vaporized while moving on a wall surface (that is, the surface of the inner wall) of the vaporization chamber 65 without stagnating there. As a result, it is possible to suppress the adhesion of the liquid source reliably. However, the surface treatment is not limited to the precision polishing. For example, a coating treatment such as a fluororesin coating treatment may be performed as the surface treatment. Even in such a case, it is possible to obtain the effect of suppressing the adhesion of the liquid source.

A discharge hole 70 is provided in the vicinity of a central portion of the vaporization chamber 65 in the vertical direction. The discharge hole 70 corresponds to an outlet of the vaporized gas generated in the vaporization chamber 65, and constitutes a part of a flow path through which the vaporized gas (source gas) is supplied to the process chamber 7. Instead of the discharge hole 70, a plurality of discharge holes 70 may be provided on a side wall of the vaporization chamber 65. In such a case, it is preferable that the plurality of discharge holes 70 are evenly arranged in a circumferential direction of the side wall of the vaporization chamber 65.

A heater “H” capable of adjusting a temperature of the wall surface of the vaporization chamber 65 is provided on an outer peripheral side of the vaporization chamber 65 so as to surround the vaporization chamber 65. With the heater H, it is possible to improve a heat transfer efficiency from the wall surface of the vaporization chamber 65. Therefore, a mist adhering to the wall surface of the vaporization chamber 65 is efficiently vaporized. Thereby, it is possible to reduce a residue on the wall surface of the vaporization chamber 65.

<First Fluid Supplier>

The first fluid supplier (which is the first fluid supply structure) A provided at the second end of the vaporization chamber 65 is connected to the vaporization chamber 65 at the second end of the vaporization chamber 65. The first fluid supplier A is configured to supply a mixed fluid in which the first carrier gas (inert gas) 88 and the liquid source 63 are mixed toward the first end of the vaporization chamber 65. That is, the first fluid supplier A is configured to eject the mixed fluid (hereinafter, also simply referred to as the mist) as an atomizing mist in which the liquid source 63 and the first carrier gas 88 are mixed into the vaporization chamber 65.

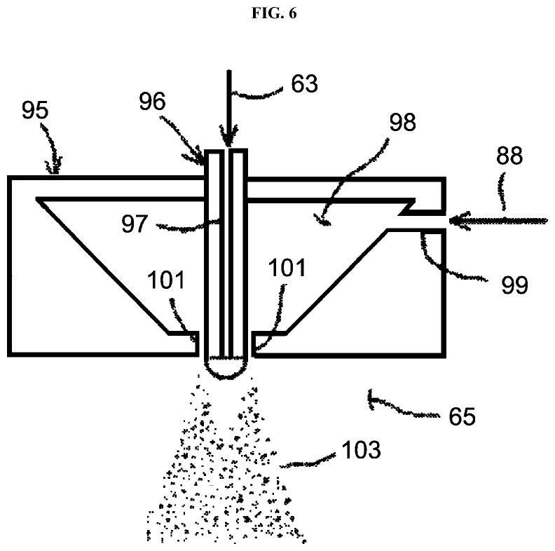

FIGS. 6 through 9 are diagrams schematically illustrating components constituting the first fluid supplier A.

As shown in FIG. 6, the first fluid supplier A includes a nozzle holder 95 facing the vaporization chamber 65 at the second end of the vaporization chamber 65.

The nozzle holder 95 is provided with a spray nozzle 96 of a two-fluid spray type through which the liquid source 63 is sprayed (or atomized) to the vaporization chamber 65. The spray nozzle 96 is of a cylindrical shape, and a spray flow path 97 through which the liquid source 63 is sprayed from the gas supply pipe 45 (see FIG. 2) to the vaporization chamber 65 is provided in the spray nozzle 96.

For example, a carrier gas chamber 98 of an inverted conical shape is provided in the nozzle holder 95. The carrier gas chamber 98 of a predetermined volume is provided so as to surround the spray nozzle 96, and the spray nozzle 96 is arranged so as to vertically penetrate the carrier gas chamber 98. A carrier gas supply hole 99 communicating with the gas supply pipe 85 (see FIG. 2) is provided in the carrier gas chamber 98, and the first carrier gas 88 is supplied through the gas supply pipe 85 via the carrier gas supply hole 99.

An atomizer ejection port (hereinafter, also simply referred to as an “ejection port”) 101 is provided at a lower surface of the carrier gas chamber 98. The ejection port 101 is provided parallel to a front end (tip) of the spray nozzle 96, and serves as a first ejection port through which the carrier gas chamber 98 communicates with the vaporization chamber 65. The ejection port 101 is provided around the spray nozzle 96.

When the liquid source 63 is vaporized using such a configuration described above, the liquid source 63 whose flow rate is adjusted by the LMFC 61 (see FIG. 2) is supplied to the spray flow path 97 through the gas supply pipe 45, and the first carrier gas 88 whose flow rate is adjusted by the MFC 86 (see FIG. 2) is supplied to the carrier gas chamber 98 through the gas supply pipe 85 and the carrier gas supply hole 99. When an inner diameter of the ejection port 101 is smaller than an inner diameter of the carrier gas supply hole 99, a pressure of the carrier gas chamber 98 is increased to a high pressure by the liquid source 63 and the first carrier gas 88 being supplied.

Then, the first carrier gas 88 in the carrier gas chamber 98 whose pressure is increased to the high pressure is further compressed and accelerated when passing through the ejection port 101, and then is ejected into the vaporization chamber 65. In addition, the liquid source 63 supplied to the spray flow path 97 is also ejected into the vaporization chamber 65 through a front end (tip) of the spray flow path 97. When the first carrier gas 88 and the liquid source 63 are ejected, at an outlet (liquid outlet) of the spray flow path 97 and an outlet of the ejection port 101, a speed difference between the liquid source 63 and the first carrier gas 88 is great. Therefore, when the liquid source 63 is torn off by the first carrier gas 88 whose speed is high, the liquid source 63 is split and atomized, and the mist containing the atomized liquid source 63 and the first carrier gas 88 mixed with each other is generated. Then, the mist is sprayed into the vaporization chamber 65 as a gas-liquid two-phase flow 103 whose speed and pressure are high.

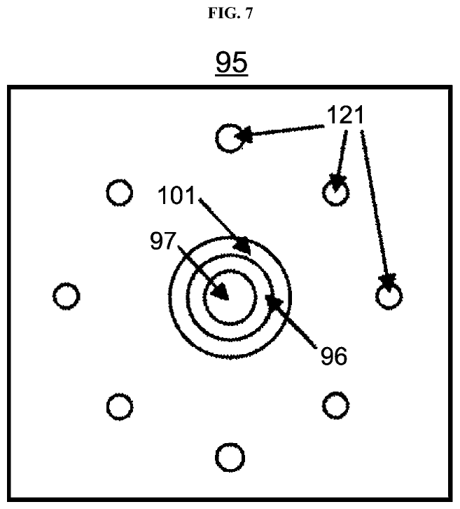

As shown in FIG. 7, a plurality of purge holes 121 are provided around the spray nozzle 96 on an outer peripheral side of the ejection port 101. The purge gas (for example, the inert gas) is supplied around the spray nozzle 96 through the plurality of purge holes 121. In combination with the plurality of purge holes 121 and a nozzle plate cover (hereinafter, also simply referred to as a “cover”) 122 described later, it is possible to provide an effect of removing a mist adhesion.

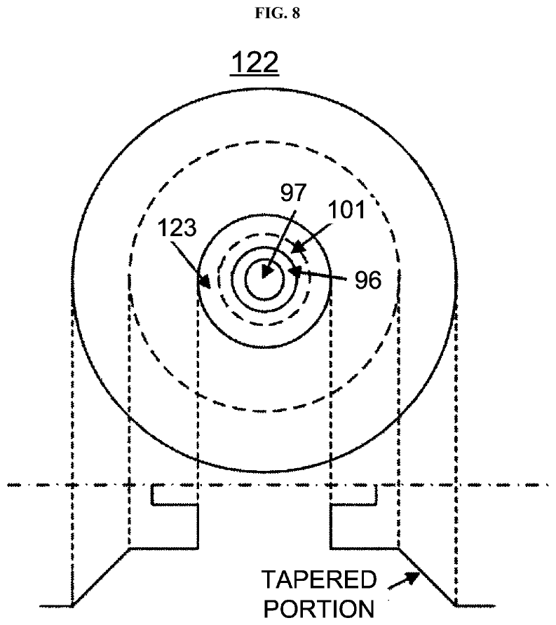

FIG. 8 is a diagram schematically illustrating an exemplary configuration of the cover 122 serving as a protective structure provided around the spray nozzle 96. In the exemplary configuration of the cover 122 shown in FIG. 8, a configuration in the vicinity of the spray nozzle 96 and the plurality of purge holes 121 is shown in FIG. 8 when the cover 122 is provided. In addition, the cover 122 is configured such that a region where the mist generated at the front end of the spray nozzle 96 flows into the nozzle holder 95 is limited to an annular port 123 excluding a cross-sectional area of the nozzle (that is, the spray nozzle 96). The annular port 123 may be made smaller depending on a state of the mist adhesion. However, due to restrictions on a vaporization performance, the annular port 123 is configured to be greater than an opening of the ejection port 101. In addition, since the purge gas is supplied to the vaporization chamber 65 through the annular port 123, the mist adhesion does not occur on the front end and a cylindrical portion of the spray nozzle 96. Thereby, it is possible to improve the effect of removing the mist adhesion. Therefore, the ejection port 101 is not blocked (or closed).

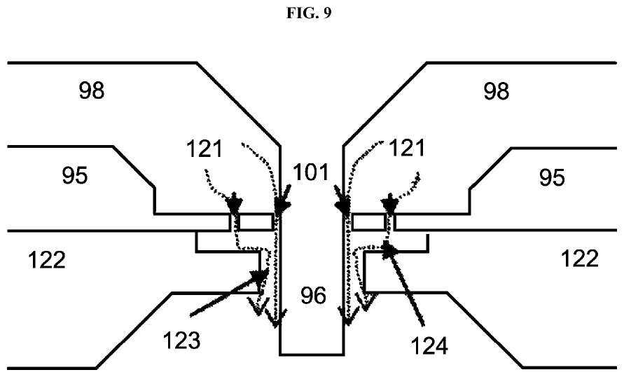

That is, as shown in FIG. 9, the first fluid supplier A includes at least the spray nozzle 96, the nozzle holder 95 provided with the plurality of purge holes 121 around the spray nozzle 96, and the cover 122 provided so as to cover the nozzle holder 95. A dotted line shown in FIG. 9 schematically illustrates a flow path of the first carrier gas 88.

As a result, by directly supplying the inert gas supplied to the ejection port 101 to the vaporization chamber 65 via the annular port 123, the liquid source 63 is converted into the mist. The inert gas supplied through the plurality of purge holes 121 passes through a space 124 serving as a purge space (hereinafter, also referred to as a “plate cover inner space”) provided in the cover 122, and then the inert gas flows into the vaporization chamber 65 through the annular port 123 in the same manner as the inert gas assisting the liquid source 63 to be converted into the mist. With such a configuration, two different gas flows due to the inert gas supplied through the ejection port 101 and the inert gas supplied through the plurality of purge holes 121 merge with each other near a boundary between the annular port 123 and the space 124. Thereby, it is possible to provide the two different gas flows in the vicinity of the annular port 123.

Hereinafter, the flow of the inert gas serving as the first carrier gas 88 in the first fluid supplier A will be described in more detail. First, the carrier gas chamber 98 is filled with the inert gas. Then, the inert gas pressurized in the carrier gas chamber 98 passes through the ejection port 101 and the plurality of purge holes 121. Then, as shown by the dotted line in FIG. 9, the inert gas ejected through the ejection port 101 passes through the purge space 124 and the annular port 123, reaches the front end of the spray nozzle 96, and atomizes the liquid source 63 to convert the liquid source 63 into the mist. The inert gas ejected through the ejection port 101 contributes to the conversion of the liquid source 63 into the mist without being hindered (that is, while maintaining the speed of the inert gas at a high speed).

On the other hand, as shown by the dotted line in FIG. 9, the inert gas that has passed through the plurality of purge holes 121 collides with the cover 122 through the purge space 124. As a result, a direction of the inert gas is changed to a direction of the spray nozzle 96 while the speed of the inert gas is reduced, and the inert gas whose speed is reduced flows along the periphery of the purge space 124 to merge with the inert gas ejected through the ejection port 101 near the annular port 123, and is supplied to the vaporization chamber 65 together with the inert gas ejected through the ejection port 101. The gas flows of the inert gas whose speed is reduced and the inert gas ejected through the ejection port 101 can provide a mist adhesion protective layer directly under the ejection port 101 and its periphery, and can provide a mist adhesion removal synergistic effect by which the mist flowing into the annular port 123 is discharged through the annular port 123.

As described above, according to the first fluid supplier A according to the present embodiments, by supplying the inert gas through the plurality of purge holes 121 in addition to the ejection port 101 in the present embodiments, although the mist atomized at the front end of the spray nozzle 96 adheres to the periphery of the annular port 123 of the cover 122, a tapered surface of the cover 122 and the front end of the spray nozzle 96, it is possible to limit the mist adhesion to a small amount in the periphery of the ejection port 101 and the cylindrical portion of the spray nozzle 96. Therefore, it is possible to provide an effect of suppressing the blockage of the ejection port 101 and the mist adhesion to the cylindrical portion of the spray nozzle 96.

As described above, by using the nozzle plate cover 122 shown in FIGS. 8 through 9, an effect of supplying the source material (that is, the liquid source 63) is exhibited to some extent. However, in the future, it is preferable to further increase a supply amount of the source material. When the supply amount of the source material is increased, the mist adhesion to the nozzle plate cover 122 may become a problem. As an amount of the gas such as the source gas consumed by the wafer 6 serving as the substrate increases due to the complexity of the semiconductor device and the increase in three-dimensional (3D) structures of the semiconductor device, it is preferable to supply more source material to the process chamber 7.

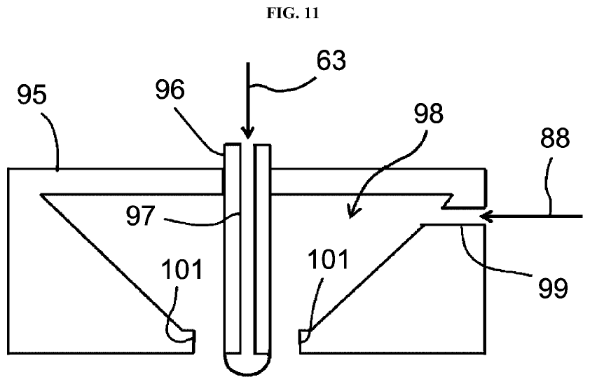

Subsequently, another example of the first fluid supplier A of the present embodiments shown in FIG. 6 will be described with reference to FIG. 11. The first fluid supplier A shown in FIG. 11 is an improved example of the first fluid supplier A shown in FIG. 6. A configuration of the first fluid supplier A shown in FIG. 11 is substantially the same as that of the first fluid supplier A shown in FIG. 6. Thus, only portions different from those of the first fluid supplier A shown in FIG. 6 will be described in detail below, and the description of portions the same as the first fluid supplier A shown in FIG. 6 will be omitted. Since an operation of vaporizing the liquid source 63 using such a configuration is basically the same as the operation in the configuration of FIG. 6, it will be briefly described below.

The liquid source 63 whose flow rate is adjusted by the LMFC 61 (see FIG. 2) is supplied to the spray flow path 97 through the gas supply pipe 45, and the first carrier gas 88 whose flow rate is adjusted by the MFC 86 (see FIG. 2) is supplied to the carrier gas chamber 98 through the gas supply pipe 85 and the carrier gas supply hole 99. Then, the first carrier gas 88 is supplied to the vaporization chamber 65 through the ejection port 101.

When the first carrier gas 88 and the liquid source 63 are ejected, at the outlet (liquid outlet) of the spray flow path 97 and the outlet of the ejection port 101, the speed difference between the liquid source 63 and the first carrier gas 88 is great, and the first carrier gas 88 whose speed is high collides with the liquid source 63. As a result, the liquid source 63 is atomized, and the mist containing the atomized liquid source 63 and the first carrier gas 88 mixed with each other is generated.

The great speed difference between the liquid source 63 and the first carrier gas 88 is caused by the first carrier gas 88 being further compressed and accelerated as it passes through the ejection port 101 under conditions that the inner diameter of the ejection port 101 is smaller than the inner diameter of the carrier gas supply hole 99, a volume of the carrier gas chamber 98 is sufficiently large, the first carrier gas 88 is filled in the carrier gas chamber 98 and the pressure of the carrier gas chamber 98 is increased to a predetermined high pressure.

In future cases where the amount of the liquid source 63 supplied to the spray flow path 97 should be further increased in accordance with an increase in the amount of the source material supplied to the process chamber 7, it is preferable to increase the inner diameter of the ejection port 101 in addition to increasing the flow rate of the first carrier gas 88 while satisfying the conditions described above.

According to the present embodiments, even when the flow rate of the liquid source 63 increases, by increasing the flow rate of the first carrier gas 88 and the inner diameter of the ejection port 101 while satisfying the conditions described above, it is possible to atomize the liquid source 63, and also possible to efficiently generate the mist containing the atomized liquid source 63 and the first carrier gas 88 mixed with each other. In addition, by mixing the mist with the second carrier gas described later, it is possible to suppress a deposition (or accumulation) of the residue in the vaporization chamber 65 and also possible to improve a vaporization efficiency.

<Second Fluid Supplier>

The second fluid supplier B provided at the first end of the vaporization chamber 65 is configured to supply the second carrier gas (inert gas) 105 from the first end toward the mixed fluid supplied into the vaporization chamber 65 from the second end of the vaporization chamber 65 by the first fluid supplier A. That is, the second fluid supplier B is configured to eject the second carrier gas 105 (which is the inert gas (hereinafter, also referred to as a “hot N₂ gas”) heated such that a thermal energy of the inert gas is sufficient for vaporizing the mist supplied by the first fluid supplier A) into the vaporization chamber 65, and to collide the second carrier gas 105 with the mist each other in the vaporization chamber 65.

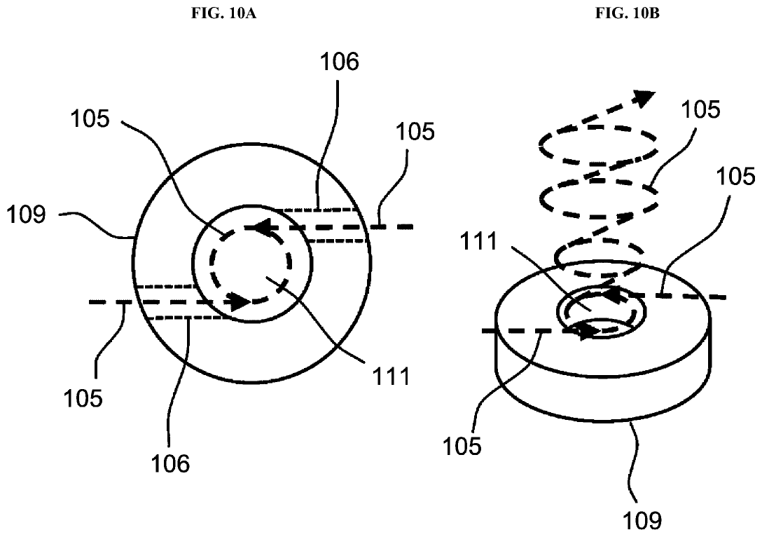

FIGS. 10A and 10B are diagrams schematically illustrating components constituting the second fluid supplier B. As shown in FIGS. 10A and 10B, the second fluid supplier B includes a plate structure 109 serving as a blow-up plate (B.UP plate) arranged so as to face an inside of the vaporization chamber 65 at one end of the second fluid supplier B.

The plate structure 109 is provided with an outlet hole (also referred to as a “second ejection hole”) 111 through which the second carrier gas 105 is ejected into the vaporization chamber 65 and a carrier gas introduction hole (or carrier gas introduction holes) 106 serving as a flow path through which the second carrier gas 105 is introduced (supplied) into the second ejection hole 111. The second ejection hole 111 is of a circular shape when viewed from above. The carrier gas introduction hole (or the carrier gas introduction holes) 106 is (are) arranged along a tangential direction of an inner wall of the plate structure 109 where the second ejection hole 111 is provided. One or more carrier gas introduction holes 106 may be provided. That is, it is preferable that a plurality of carrier gas introduction holes 106 (for example, two carrier gas introduction holes 106 shown in FIG. 10A) are provided. As shown in FIG. 10B, the two second carrier gases 105 supplied to the second ejection hole 111 through the two carrier gas introduction holes 106 are mixed so as not to obstruct the flows thereof.

In the plate structure 109 configured as described above, when the second carrier gas 105 is ejected into the vaporization chamber 65, the second carrier gas 105 is supplied from the carrier gas introduction hole (or the carrier gas introduction holes) 106 toward the second ejection hole 111. Since the carrier gas introduction hole (or the carrier gas introduction holes) 106 is (are) arranged along the tangential direction of the inner wall of the plate structure 109 where the second ejection hole 111 is provided, when the second carrier gas 105 is supplied through the carrier gas introduction hole (or the carrier gas introduction holes) 106, the second carrier gas 105 at the second ejection hole 111 may form a flow of a spiral shape. As shown in FIG. 10B, the two second carrier gases 105 are mixed so as to promote the flows thereof rather than obstructing the flows thereof. Therefore, by ejecting the second carrier gas 105 to the vaporization chamber 65 through the plurality of carrier gas introduction holes 106 and the second ejection hole 111, it is possible to supply the second carrier gas 105 at a larger flow rate.

Therefore, the second carrier gas 105 flowing in the spiral shape is ejected through the plate structure 109 in the second fluid supplier B. Then, the second carrier gas 105 flows upward while being rotated in the vaporization chamber 65. Due to such a flow of the second carrier gas 105, in the vaporization chamber 65, the second carrier gas 105 ejected by the second fluid supplier B flows upward along a surface of a wall of the tapered portion 73 provided on a lower portion of the vaporization chamber 65. That is, the vaporization chamber 65 and the second fluid supplier B are configured such that the second carrier gas 105 supplied by the second fluid supplier B to the vaporization chamber 65 flows along the inner wall of the vaporization chamber 65.

In addition to or instead of the configuration described above, the second fluid supplier B may be configured to form the flow of the spiral shape by providing a pipe through which the second carrier gas 105 flows in the tangential direction along the inner wall of the vaporization chamber 65.

<Gas Flow in Vaporization Chamber>

Hereinafter, the flow of the gas in the vaporization chamber 65 constituting the vaporizer 56 will be described in more detail.

As described above, the vaporizer 56 is provided with the first fluid supplier A at the second end of the vaporization chamber 65 and the second fluid supplier B at the first end of the vaporization chamber 65, and each of the first fluid supplier A and the second fluid supplier B is configured to perform a gas ejection. That is, the vaporizer 56 is configured such that the gas ejection is performed at each of vertically opposing surfaces of the vaporization chamber 65. Specifically, through the first fluid supplier A, the liquid source 63 converted into the mist by the first carrier gas 88 is sprayed (or atomized) into the vaporization chamber 65. In addition, through the second fluid supplier B, the second carrier gas 105 (hot N₂ gas) whose thermal energy is sufficient for vaporizing the mist supplied by the first fluid supplier A is ejected into the vaporization chamber 65 for the purpose of assisting the vaporization of the mist.

In that case, when the gas from each of the first fluid supplier A and the second fluid supplier B forms a linear flow toward the vertically opposing surfaces of the vaporization chamber 65, the mist sprayed through the first fluid supplier A hits the wall surface of the vaporization chamber 65 unevenly, and a temperature of a part of the wall surface of the vaporization chamber 65 may be locally lowered. Thereby, the liquid source 63 may be insufficiently vaporized, and the residue may be deposited (or accumulated) in the vaporization chamber 65. That is, when the mist supplied by the first fluid supplier A is sprayed toward the second carrier gas 105 (hot N₂ gas) supplied from the lower portion of the vaporization chamber 65, there may be a local space where the mist does not hit the second carrier gas 105 due to the imbalance of the flow. As a result, the mist may adhere to a lower surface of the vaporization chamber 65 and may cause the deposition of the residue. When a region in which the residue adheres to the lower surface of the vaporization chamber 65 increases, the vaporization efficiency in the vaporization chamber 65 may decrease, and a progress of depositing of the residue may be accelerated.

As described above, when the vaporized gas is generated in the vaporization chamber 65, if the liquid source 63 is insufficiently vaporized, the deposition of the residue may occur. Thereby, the vaporization efficiency may decrease. Therefore, it is preferable to sufficiently mix the mist and the second carrier gas 105 to vaporize the mist to improve the vaporization efficiency. It is also preferable to sufficiently mix the mist and the second carrier gas 105 to suppress the deposition of the residue even when the mist adheres to the inner wall of the vaporization chamber 65.

In the vaporizer 56 according to the present embodiments, the second carrier gas (hot N₂ gas) 105 supplied by the second fluid supplier B flows so as to cover the entirety of the inner wall of the vaporization chamber 65 at least up to the discharge hole 70. More specifically, the second carrier gas 105 ejected from the lower portion of the vaporization chamber 65 does not form a linear flow toward the mist but flows in the spiral shape toward an upper portion of the vaporization chamber 65 by flowing upward while being rotated along the inner wall of the vaporization chamber 65.

Therefore, in the vaporization chamber 65, the second carrier gas 105 of the spiral shape flows so as to wrap the mist supplied by the first fluid supplier A from an outer periphery of the mist. As a result, it is possible to prevent the mist sprayed into the vaporization chamber 65 from hitting the wall surface of the vaporization chamber 65 unevenly. Further, even when the mist adheres to the wall surface of the vaporization chamber 65, the mist is heated by the second carrier gas 105 such that the mist is vaporized before being deposited on the wall surface of the vaporization chamber 65 as the residue. From these facts, in the vaporizer 56 according to the present embodiments, the second carrier gas 105 (hot N₂ gas) from the second fluid supplier B flows in the spiral shape along the inner wall of the vaporization chamber 65, as compared with a case of a conventional linear flow of the second carrier gas 105. Thus, it is possible to prevent the residue from depositing (or accumulating) in the vaporization chamber 65, and as a result, it is also possible to improve the vaporization efficiency in the vaporization chamber 65.

In addition, according to the present embodiments, as compared with the case of the conventional linear flow of the second carrier gas 105, the second carrier gas 105 flows in a circumferential direction of the inner wall of the vaporization chamber 65. Therefore, as compared with the case of the conventional linear flow of the second carrier gas 105, it is possible to lengthen the time of stagnating in the vaporization chamber 65 in a state where the mist and the second carrier gas 105 are mixed. As a result, it is possible to improve the vaporization efficiency in the vaporization chamber 65, and it is also possible to supply the vaporized gas obtained by vaporizing the liquid source 63 at a larger flow rate. In addition, according to the present embodiments, the second carrier gas 105 may flow in the circumferential direction of the side wall of the vaporization chamber 65 along the inner wall of the vaporization chamber 65. Therefore, as compared with the case of the conventional linear flow of the second carrier gas 105, the second carrier gas 105 is efficiently discharged through the plurality of discharge holes 70 provided in the circumferential direction of the side wall of the vaporization chamber 65. As a result, it is possible to supply the vaporized gas obtained by vaporizing the liquid source 63 at a larger flow rate.

(4) Effects according to Present Embodiment

According to the present embodiments described above, it is possible to provide one or more of the following effects.

(a) According to the present embodiments, by allowing the second carrier gas 105 to flow along the inner wall of the vaporization chamber 65, it is possible to suppress the deposition of the residue in the vaporization chamber 65, and it is also possible to improve the vaporization efficiency when generating the vaporized gas.

(b) According to the present embodiments, by allowing the second carrier gas 105 to flow in the spiral shape, it is possible to more reliably suppress the deposition of the residue and to more reliably improve the vaporization efficiency. That is, the present embodiments are very useful for suppressing the deposition of the residue in the vaporization chamber 65 and for improving the vaporization efficiency.

(c) According to the present embodiments, by allowing the second carrier gas 105 to flow upward while being rotated in the vaporization chamber 65, it is possible to more reliably suppress the deposition of the residue and to more reliably improve the vaporization efficiency. That is, the present embodiments are very useful for suppressing the deposition of the residue in the vaporization chamber 65 and for improving the vaporization efficiency.

(d) According to the present embodiments, since the surface treatment such as the precision polishing and the coating treatment is performed on the inner wall of the vaporization chamber 65, it is possible to suppress the adhesion of the liquid source 63 to the surface of the inner wall of the vaporization chamber 65. Therefore, the present embodiments are very useful for suppressing the deposition of the residue in the vaporization chamber 65 and for improving the vaporization efficiency.

(e) According to the present embodiments, since the second carrier gas 105 flows upward while being rotated in the spiral shape along the inner wall of the vaporization chamber 65, even when the liquid source 63 adheres to the surface of the inner wall of the vaporization chamber 65, it is possible to heat the liquid source 63 by the second carrier gas 105 to vaporize the liquid source 63. Therefore, it is possible to suppress the adhesion of the liquid source 63 to the surface of the inner wall of the vaporization chamber 65.

(f) According to the present embodiments, since the second carrier gas 105 flows in the circumferential direction of the side wall of the vaporization chamber 65 along the inner wall of the vaporization chamber 65, it is possible to heat the entirety of the surface of the side wall of the vaporization chamber 65 by the second carrier gas 105 at least up to the discharge hole 70 so as to vaporize the liquid source 63. Therefore, it is possible to more reliably suppress the deposition of the residue and to more reliably improve the vaporization efficiency.

(g) According to the present embodiments, since the second carrier gas 105 flows in the circumferential direction of the side wall of the vaporization chamber 65 along the inner wall of the vaporization chamber 65, it is possible to lengthen the time for the second carrier gas 105 to reach the discharge hole 70. Thereby, it is possible to lengthen the time of mixing the second carrier gas 105 with the liquid source 63. As a result, it is possible to vaporize the liquid source 63 efficiently. Therefore, it can contribute to increasing the flow rate of the source gas which is the vaporized gas.

(h) According to the present embodiments, since the second carrier gas 105 flows in the circumferential direction of the side wall of the vaporization chamber 65 along the inner wall of the vaporization chamber 65, the second carrier gas 105 is efficiently discharged through the plurality of discharge holes 70 provided in the circumferential direction of the side wall of the vaporization chamber 65. Thereby, it is possible to discharge the vaporized gas obtained by vaporizing the liquid source 63. Therefore, it can contribute to increasing the flow rate of the source gas which is the vaporized gas.

(5) Modified Example (Other Embodiments)>

While the technique of the present disclosure is described in detail by way of the embodiments described above, the above-described technique is not limited thereto. The above-described technique may be modified in various ways without departing from the scope thereof.

For example, a supply pipe (for example, the gas supply pipe 91) of the second carrier gas 105 may be of a spiral shape such that the second carrier gas 105 flows along the inner wall of the vaporization chamber 65. Further, in order to flow the second carrier gas 105 upward while being rotated, a flow path of the second carrier gas 105 may be inclined slightly upward instead of horizontally. An inclination angle of the flow path of the second carrier gas 105 is as small as possible, for example, 10° or less, preferably 5° or less. Thereby, the second carrier gas 105 flows upward while being rotated along the inner wall of the vaporization chamber 65. For example, the surface treatment may be performed on the inner wall of the vaporization chamber 65 located closer to the second fluid supplier B than the discharge hole 70 so as to suppress the adhesion of the liquid source 63.

For example, in the embodiments described above, a zirconium (Zr) source such as tetrakis(ethylmethylamino)zirconium (TEMAZ, ZrN(CH₃)C₂H₅]₄), tetrakis (diethylamino)zirconium (TDEAZ, Zr[N(C₂H₅)₂]₄) and tetrakis(dimethylamino)zirconium (TDMAZ, Zr[N(CH₃)₂]₄) may be used as the liquid source 63 to form the metal oxide film.

For example, the substrate processing apparatus according to the embodiments described above may be preferably applied to a type of film using a liquid source whose vapor pressure is low. For example, the substrate processing apparatus according to the embodiments described above may be preferably applied to a process of forming a nickel film (Ni film) on the wafer 6 using Ni-amidinate as the source gas or a process of forming a cobalt film (Co film) on the wafer 6 using Co-amidinate as the source gas.

As described above, according to some embodiments in the present disclosure, it is possible to suppress the deposition of the residue and also possible to improve the vaporization efficiency.

What is claimed is:

1. A vaporizing system comprising:
a vaporization chamber provided with a first end and a second end;
a first fluid supplier connected to the vaporization chamber at the second end and configured to supply toward the first end a mixed fluid containing a first carrier gas and a liquid source mixed with each other; and
a second fluid supplier connected to the vaporization chamber at the first end and configured to supply a second carrier gas such that the second carrier gas flows along an inner wall of the vaporization chamber when being supplied through the first end.

2. The vaporizing system of claim 1, wherein the second fluid supplier is configured such that the second carrier gas flows in a spiral shape in the vaporization chamber.

3. The vaporizing system of claim 1, wherein the first end is provided at a lower portion of the vaporization chamber, and
the second carrier gas supplied by the second fluid supplier is configured to flow upward while being rotated in the vaporization chamber.

4. The vaporizing system of claim 1, wherein the second carrier gas comprises a heated inert gas.

5. The vaporizing system of claim 1, wherein a side wall of the vaporization chamber is provided with a discharge hole through which a vaporized gas obtained by vaporizing the mixed fluid by the second carrier gas is discharged from the vaporization chamber.

6. The vaporizing system of claim 1, wherein a side wall of the vaporization chamber is provided with a plurality of discharge holes evenly arranged in a circumferential direction thereof, wherein a vaporized gas obtained by vaporizing the mixed fluid by the second carrier gas is discharged from the vaporization chamber through the plurality of discharge holes.

7. The vaporizing system of claim 1, wherein a surface treatment is performed on a surface of the inner wall of the vaporization chamber so as to suppress an adhesion of the liquid source.

8. The vaporizing system of claim 7, wherein the surface treatment comprises a precision polishing.

9. The vaporizing system of claim 7, wherein the surface treatment comprises a coating treatment.

10. The vaporizing system of claim 5, wherein a surface treatment is performed on the inner wall of the vaporization chamber located closer to the second fluid supplier than the discharge hole so as to suppress an adhesion of the liquid source.

11. The vaporizing system of claim 1, wherein the second fluid supplier comprises:
a structure into which the second carrier gas is introduced; and
an outlet hole provided in the structure such that the second carrier gas flows into the outlet hole via an introduction hole provided in the structure.

12. The vaporizing system of claim 11, wherein the introduction hole is provided along a tangential direction of an inner wall of the structure where the outlet hole is provided.

13. The vaporizing system of claim 11, wherein one or more introduction holes are further provided in the structure so as not to obstruct a flow of the second carrier gas supplied to the outlet hole.

14. The vaporizing system of claim 1, wherein a speed at which the first carrier gas is introduced into the vaporization chamber is greater than a speed at which the liquid source is introduced into the vaporization chamber.

15. The vaporizing system of claim 1, wherein the first fluid supplier comprises:
a carrier gas chamber of a predetermined volume; and
a spray nozzle arranged so as to vertically penetrate the carrier gas chamber, and
wherein a carrier gas supply hole through which the first carrier gas is introduced is provided in the carrier gas chamber.

16. The vaporizing system of claim 15, wherein an ejection port provided parallel to a front end of the spray nozzle and through which the carrier gas chamber communicates with the vaporization chamber is provided at a lower surface of the carrier gas chamber.

17. The vaporizing system of claim 16, wherein the ejection port is provided around the front end of the spray nozzle.

18. The vaporizing system of claim 17, wherein an inner diameter of the ejection port is smaller than an inner diameter of the carrier gas supply hole.

19. A substrate processing apparatus at least comprising:
a process chamber in which a substrate is processed;
a vaporizer configured to generate a vaporized gas by vaporizing a liquid source; and
a source gas supplier configured to supply the vaporized gas as a source gas into the process chamber,
wherein the vaporizer comprises:
a vaporization chamber provided with a first end and a second end;
a first fluid supplier connected to the vaporization chamber at the second end and configured to supply toward the first end a mixed fluid containing a first carrier gas and a liquid source mixed with each other; and
a second fluid supplier connected to the vaporization chamber at the first end and configured to supply a second carrier gas such that the second carrier gas flows along an inner wall of the vaporization chamber when being supplied through the first end.

20. A method of manufacturing a semiconductor device, comprising:
(a) supplying a source gas into a process chamber in which a substrate is accommodated;
(b) removing the source gas from the process chamber;
(c) supplying a reactive gas into the process chamber in which the source gas is removed; and
(d) removing the reactive gas from the process chamber,
wherein a vaporized gas obtained by vaporizing a liquid source by a vaporizer is supplied as the source gas in (a), and
wherein the vaporizer comprises:
a vaporization chamber provided with a first end and a second end;
a first fluid supplier connected to the vaporization chamber at the second end and configured to supply toward the first end a mixed fluid containing a first carrier gas and a liquid source mixed with each other; and
a second fluid supplier connected to the vaporization chamber at the first end and configured to supply a second carrier gas such that the second carrier gas flows along an inner wall of the vaporization chamber when being supplied through the first end.
